(19) United States
(12) Patent Application Publication
(10) Pub. No.: US 2026/0068271 A1
(43) Pub. Date: Mar. 5, 2026

(54) SEMICONDUCTOR DEVICE AND METHOD OF FABRICATING THE SAME

(71) Applicant: Samsung Electronics Co., Ltd., Suwon-si (KR)

(72) Inventors: Sungmin KIM, Suwon-si (KR); Deokhwan KIM, Suwon-si (KR); Jaemyeong KIM, Suwon-si (KR); Jeonggeol KIM, Suwon-si (KR); Yongkyung LEE, Suwon-si (KR)

(73) Assignee: Samsung Electronics Co., Ltd., Suwon-si (KR)

(21) Appl. No.: 19/282,640

(22) Filed: Jul. 28, 2025

(30) Foreign Application Priority Data
Sep. 4, 2024 (KR) 10-2024-0120312

(51) Int. Cl. H10D 64/23; H01L 23/528; H10D 30/00; H10D 30/01; H10D 30/47; H10D 62/10; H10D 64/27

(52) U.S. Cl. CPC H10D 64/258; H10D 30/0191; H10D 30/502; H10D 64/518; H10D 30/481; H10D 62/121

(57) ABSTRACT

Provided are semiconductor devices and methods of fabricating the semiconductor device. The semiconductor device includes a channel, a first source/drain and a second source/drain being apart from each other in a first direction with the channel therebetween, a gate electrode surrounding the channel, an alternating-current wiring line configured to provide alternating current to the channel, and a first conductive contact connecting the alternating-current wiring line and the first source/drain to each other. A height difference from a first surface of the gate electrode facing the alternating-current wiring line to a first surface of the first source/drain in contact with the first conductive contact is less a height difference from a second surface of the gate electrode opposing the first surface of the gate electrode to a second surface of the first source/drain opposing the first surface of the first source/drain.

### CROSS-REFERENCE TO RELATED APPLICATION

This application is based on and claims priority under 35 U.S.C. § 119 to Korean Patent Application No. 10-2024-0120312, filed on Sep. 4, 2024, in the Korean Intellectual Property Office, the disclosure of which is incorporated by reference herein in its entirety.

### BACKGROUND

### 1. Field

The disclosure relates to semiconductor devices and methods of fabricating the semiconductor device.

### 2. Description of the Related Art

Recently, the downscaling of semiconductor devices has progressed rapidly. In addition, semiconductor devices require not only higher operating speeds but also functional accuracy, which has led to optimization of the transistor structures of semiconductor devices.

To reduce the resistance of gate electrodes, it is desired to increase the size of gate electrodes. However, the parasitic capacitance between gate electrodes and alternating-current wiring lines increases as the sizes of gate electrodes increase.

### SUMMARY

Provided are semiconductor devices with reduced parasitic capacitance and methods of fabricating the semiconductor device.

Provided are semiconductor devices in which upper and lower gate electrodes are adjusted to have different heights according to the types of wiring lines to allow the semiconductor device to operate at a higher speed.

Additional aspects will be set forth in part in the description which follows and, in part, will be apparent from the description, or may be learned by practice of the presented example embodiments of the disclosure.

According to an example embodiment of the disclosure, a semiconductor device includes a channel, a first source/drain and a second source/drain being apart from each other in a first direction with the channel therebetween, a gate electrode surrounding the channel, an alternating-current wiring line being apart from the first source/drain in a second direction perpendicular to the first direction and configured to provide an alternating current to the channel, and a first conductive contact connecting the alternating-current wiring line and the first source/drain to each other, wherein a first height defined as a height difference in the second direction from a first surface of the gate electrode facing the alternating-current wiring line to a first surface of the first source/drain in contact with the first conductive contact is less than a second height defined as a height difference in the second direction from a second surface of the gate electrode opposing the first surface of the gate electrode to a second surface of the first source/drain opposing the first surface of the first source/drain.

The first height may be less than or equal to ½ of the second height.

The first height may be 20 nm or less.

The second height may be 30 nm or more.

The gate electrode may have a thickness of 60 nm or more in the second direction.

The first surface of the first source/drain and the first surface of the gate electrode may be arranged on an identical plane.

A distance between the gate electrode and the first conductive contact in the second direction may be less than about 10 nm.

The semiconductor device may further include a direct-current wiring line configured to provide a direct current to the channel, and a second conductive contact connecting the direct-current wiring line and the second source/drain to each other.

The second conductive contact may be in contact with a surface of the second source/drain corresponding to the second surface of the first source/drain.

The second conductive contact may be in contact with a surface of the second source/drain corresponding to the first surface of the first source/drain.

The semiconductor device may further include a gate wiring line configured to provide a gate signal to the gate electrode, and a gate contact connecting the gate wiring line and the gate electrode to each other, wherein the gate contact may be in contact with a surface of the gate electrode corresponding to the second surface of the first source/drain.

The semiconductor device may further include a substrate supporting the gate electrode, the first source/drain, and the second source/drain, wherein the alternating-current wiring line may be on a lower surface of the substrate, and the first conductive contact penetrates the substrate.

A height of a lower surface of the first source/drain relative to the substrate may be equal to a height of a lower surface of the gate electrode relative to the substrate.

The channel may have a multi-bridge channel (MBC) structure.

The gate electrode may have a gate-all-around (GAA) structure.

According to another example embodiment of the disclosure, a method of fabricating a semiconductor device includes alternately stacking a plurality of sacrificial layers and a plurality of semiconductor layers on a substrate, forming a dummy gate electrode structure on an uppermost semiconductor layer among the plurality of semiconductor layers that are stacked, selectively etching portions of the plurality of sacrificial layers and the plurality of semiconductor layers by using the dummy gate electrode structure to form a channel from the plurality of semiconductor layers, forming a first source/drain and a second source/drain at both ends of the channel on the substrate, respectively, sequentially forming a gate insulating layer and a gate electrode using the plurality of sacrificial layers that are selectively etched, forming a first conductive contact on the first source/drain and an alternating-current wiring line on the first conductive contact; and forming a second conductive contact on the second source/drain and a direct-current wiring line on the second conductive contact, wherein a first height defined as a height difference from a first surface of the gate electrode facing the alternating-current wiring line to a first surface of the first source/drain in contact with the first conductive contact, is less than a second height defined as a height difference from a second surface of the gate electrode opposing the first surface of the gate electrode to a second surface of the first source/drain opposing the first surface of the first source/drain.

The first height may be less than or equal to ½ of the second height.

The first height may be 20 nm or less.

The forming the second conductive contact forms the second conductive contact to contact a surface of the second source/drain corresponding to the second surface of the first source/drain.

The method may further include forming a gate contact on the gate electrode and a gate wiring line on the gate contact such that the gate contact contacts a surface of the gate electrode corresponding to the second surface of the first source/drain.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1A is a cross-sectional view illustrating a semiconductor device;

FIG. 1B is another cross-sectional view illustrating the semiconductor device shown in FIG. 1A;

FIGS. 2A to 2I are reference views illustrating a method of fabricating a semiconductor device according to an example embodiment;

FIG. 3A is a view illustrating a semiconductor device according to another example embodiment;

FIG. 3B is a view illustrating the semiconductor device of FIG. 3A from another perspective;

FIG. 4 is a view illustrating a semiconductor device according to another example embodiment;

FIG. 5 is a view illustrating a semiconductor device according to another example embodiment;

FIG. 6 is a view illustrating a semiconductor device according to another example embodiment;

FIG. 7A is a view illustrating a semiconductor device according to another example embodiment;

FIG. 7B is a view illustrating the semiconductor device of FIG. 7A from another perspective;

FIG. 8 is a plan view illustrating a semiconductor apparatus according to an example embodiment;

FIG. 9 is a plan view of a logic cell region shown in FIG. 8 and illustrates the semiconductor apparatus according to an example embodiment; and

FIGS. 10A to 10D are cross-sectional views respectively taken along lines A-A′, B-B′, C-C′, and D-D′ of FIG. 9.

### DETAILED DESCRIPTION

Reference will now be made in detail to some example embodiments, examples of which are illustrated in the accompanying drawings, wherein like reference numerals refer to like elements throughout. In this regard, the present example embodiments may have different forms and should not be construed as being limited to the descriptions set forth herein. Accordingly, the present example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, semiconductor devices and methods of fabricating the semiconductor devices will be described according to various example embodiments with reference to the accompanying drawings. In the drawings, like reference numerals refer to like elements, and the sizes of elements may be exaggerated for clarity of illustration.

The terms of a singular form may include plural forms unless otherwise mentioned. It will be further understood that the terms “comprises” and/or “comprising” used herein specify the presence of stated features or elements, but do not preclude the presence or addition of one or more other features or elements. In the drawings, the sizes or thicknesses of elements may be exaggerated for clarity of illustration. In addition, when a material layer is referred to as being “above” or “on” a substrate or another layer, it may be directly on the substrate or the other layer while making contact with the substrate or the other layer or may be above the substrate or the other layer with a third layer therebetween. In the following descriptions of the example embodiments, a material of each layer is merely an example, and another material may be used.

In the disclosure, terms such as “unit” or “module” may be used to denote a unit that has at least one function or operation and is implemented with hardware, software, or a combination of hardware and software.

Specific executions described herein are merely examples and do not limit the scope of the disclosure in any way. For simplicity of description, other functional aspects of conventional electronic configurations, control systems, software and the systems may be omitted.

Furthermore, line connections or connection members between elements depicted in the drawings represent functional connections and/or physical or circuit connections by way of example, and in actual applications, they may be replaced or embodied as various additional functional connections, physical connections, or circuit connections.

An element referred to with the definite article or a demonstrative determiner may be construed as the element or the elements even though it has a singular form.

Operations of a method may be performed in appropriate order unless explicitly described in terms of order or described to the contrary. In addition, some terms (for example, “such as” and “etc.”) are used for the purpose of description and are not intended to limit the scope of the disclosure unless defined by the claims.

Expressions such as “at least one” preceding a list of elements specify the entire list of elements and do not specify individual elements within the list. For example, expressions such as “at least one of A, B, and C,” “at least one of A, B, or C,” or “at least one selected from the group consisting of A, B, and C” may be interpreted as indicating only A, only B, only C, or any combination of two or more of A, B, and C such as ABC, AB, BC, and AC.

When terms such as “about,” “approximately” or “substantially” are used in relation to a numerical value, the numerical value may be interpreted as including fabricating or operational variations from the numerical value (for example, a variation of ±10%). Furthermore, when terms such as “generally” and “substantially” are used in relation to geometric shapes, geometric precision may not be required, and permissible variations of the geometric shapes may be within the scope of example embodiments. In addition, regardless of whether numerical values or shapes are qualified or described by “approximately” or “substantially,” the numerical values or shapes may be interpreted as including fabricating or operational variations from the numerical values or shapes (for example, a variation of ±10%).

It will be understood that although terms such as “first” and “second” are used herein to describe various elements, these elements should not be limited by these terms. These terms are only used to distinguish one element from other elements.

Examples or certain terms are just used herein to describe technical ideas and should not be considered for purposes of limitation unless defined by the claims.

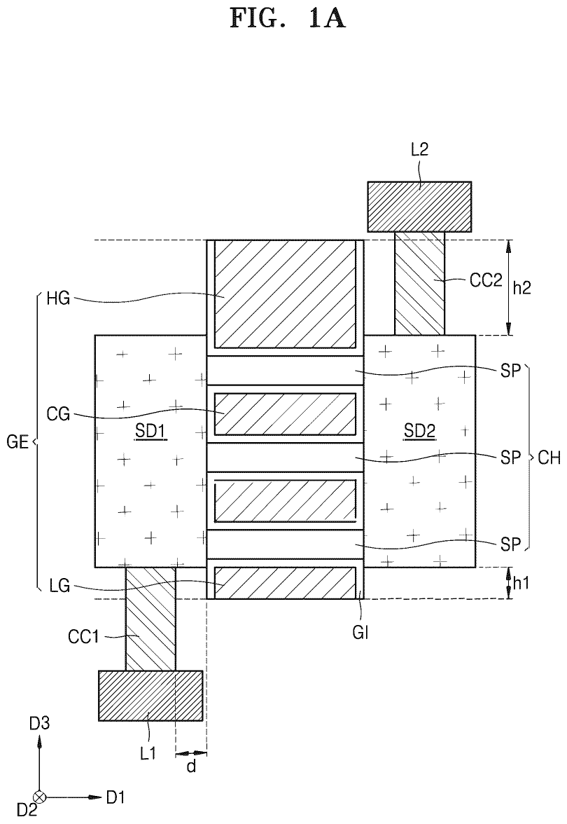

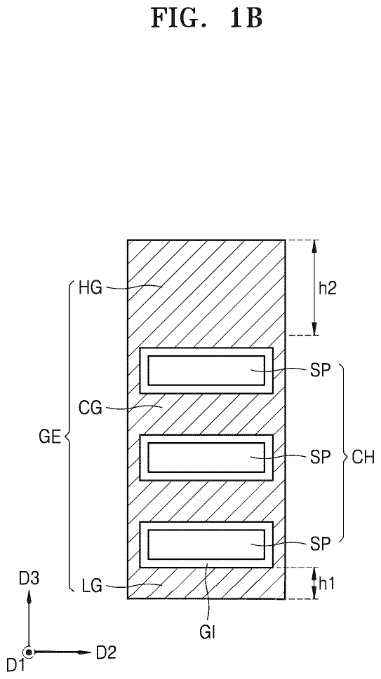

FIG. 1A is a cross-sectional view illustrating a semiconductor device, and FIG. 1B is a view illustrating another cross-sectional view of the semiconductor device shown in FIG. 1A.

Referring to FIGS. 1A and 1B, the semiconductor device may include a channel CH, a first source/drain SD1, and a second source/drain SD2. The first source/drain SD1 and the second source/drain SD2 may be arranged apart from each other in a first direction D1 with the channel CH therebetween.

The channel CH may have a multi-bridge channel structure in which a plurality of semiconductor layers SP are arranged apart from each other in a direction (for example, a third direction D3). The semiconductor layers SP may have nanoscale thicknesses and may thus be referred to as nanosheets. Although FIGS. 1A and 1B illustrate three semiconductor layers SP, example embodiments are not limited thereto. The channel CH may include at least two semiconductor layers or may include only one semiconductor layer.

The multi-bridge channel structure may reduce short channel effects and may reduce areas occupied by the first source/drain SD1 and the second source/drain SD2, facilitating or guaranteeing a higher degree of integration. In addition, the multi-bridge channel structure ensures maintaining uniform source/drain junction capacitance regardless of the position of the channel CH, allowing the semiconductor device to be used as a higher-speed and higher-reliability device.

Each of the semiconductor layers SP may include silicon (Si), germanium (Ge), silicon-germanium (SiGe), or a Group III-V semiconductor material. For example, each of the semiconductor layers SP may include crystalline silicon.

In some example embodiments, each of the semiconductor layers SP may include a two-dimensional semiconductor. For example, the two-dimensional semiconductor may include at least one selected from graphene, black phosphorous, and transition metal dichalcogenide (TMD). Graphene is a material with carbon atoms bonded two-dimensionally in a hexagonal honeycomb structure, offering higher electron mobility and superior or better thermal properties compared to silicon (Si), as well as chemical stability and a large surface area. Furthermore, black phosphorous is a material in which black phosphorous atoms are bonded two-dimensionally.

In some example embodiments, each of the semiconductor layers SP may include an oxide semiconductor. The oxide semiconductor may include an oxide of a material selected from Group 12, 13, and 14 metal elements, such as zinc (Zn), indium (In), gallium (Ga), tin (Sn), cadmium (Cd), germanium (Ge), hafnium (Hf), and combinations thereof. For example, each of the semiconductor layers SP may include a Zn oxide-based material such as Zn oxide, In—Zn oxide, or In—Ga—Zn oxide.

The first source/drain SD1 and the second source/drain SD2 of the semiconductor device may be apart from each other in the first direction D1 with the channel CH therebetween. An end of the channel CH may be connected to the first source/drain SD1, and the other end of the channel CH may be connected to the second source/drain SD2. Each of the first source/drain SD1 and the second source/drain SD2 may include a semiconductor material doped with a dopant of a conductivity type (for example, a p-type or an n-type).

The semiconductor device may further include a gate electrode GE that is apart from the channel CH, the first source/drain SD1, and the second source/drain SD2. The gate electrode GE may surround the channel CH. The gate electrode GE may surround the channel CH in a gate-all-around (GAA) structure. For example, four sides of each of the semiconductor layers SP of the channel CH may be surrounded by the gate electrode GE. Here, the four sides may include both sides in a second direction D2 and both sides in the third direction D3. When the gate electrode GE has a small thickness, gate resistance may increase, and thus, the operating speed of the semiconductor device may decrease. Therefore, in an example embodiment, the size of the gate electrode GE in the third direction D3 (that is, the thickness of the gate electrode GE) may be greater than or equal to about 60 nm.

The gate electrode GE may include a lower gate electrode LG positioned below the semiconductor layers SP in the third direction D3, an intermediate gate electrode CG positioned between the semiconductor layers SP, and an upper gate electrode HG positioned above the semiconductor layers SP. A portion of the upper gate electrode HG may protrude from at least one selected from upper surfaces of the first source/drain SD1 and the second source/drain SD2, or a portion of the lower gate electrode LG may protrude from at least one selected from lower surfaces of the first source/drain SD1 and the second source/drain SD2.

The gate electrode GE may include metal, metal nitride, metal carbide, or a combination thereof. The metal may be selected from Ti, W, Ru, Nb, Mo, Hf, Ni, Co, Pt, Yb, Tb, Dy, Er, Al, La, and Pd. The metal nitride may be selected from TiN and TaN. The metal carbide may be TiAlC. In an example embodiment, the gate electrode GE may have a TiN layer, a TiAlC/TiN stacked structure, a TiAlC/TiN/W stacked structure, a TiN/TaN/TiAlC/TiN/W stacked structure, or a TiN/TaN/TiN/TiAlC/TiN/W stacked structure. Hower, example embodiments are not limited thereto.

The semiconductor device may further include gate insulating layers GI provided between the channel CH and the gate electrode GE, between the gate electrode GE and the first source/drain SD1, and between the gate electrode GE and the second source/drain SD2.

The gate insulating layers GI may each include a silicon oxide layer, a silicon oxynitride layer, and/or a high-k layer. In an example embodiment, the gate insulating layers GI may each include a silicon oxide layer directly covering a surface of a semiconductor layer SP and a high-k layer provided on the silicon oxide layer. In other words, the gate insulating layers GI may each have a multi-layer structure including the silicon oxide layer and the high-k layer.

The high-k layer may include a high-k material having a dielectric constant greater than the dielectric constant of the silicon oxide layer. For example, the high-k material may include at least one selected from hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

The semiconductor device may further include a first wiring line L1 that provides a first electrical signal to the channel CH. The first wiring line L1 may be apart from the first source/drain SD1 in the third direction D3 that is orthogonal to the first direction D1 and the second direction D2. The first electrical signal may be an alternating-current signal. The first wiring line L1 that provides alternating current may be referred to as an alternating-current wiring line.

The first wiring line L1 may include a conductive material. For example, the first wiring line L1 may include at least one metal selected from aluminum, copper, tungsten, molybdenum, ruthenium, and cobalt.

The semiconductor device may further include a first conductive contact CC1 that connects the first wiring line L1 and the first source/drain SD1 to each other. An end of the first conductive contact CC1 may be in contact with the first wiring line L1, and the other end of the first conductive contact CC1 may be in contact with the first source/drain SD1. The first conductive contact CC1 may be a conductive via contact that is filled in a via formed in an insulating layer between the first source/drain SD1 and the first wiring line L1.

The semiconductor device may further include a second wiring line L2 that provides a second electrical signal to the channel CH. The second wiring line L2 may be apart from the second source/drain SD2 in the third direction D3 that is orthogonal to the first direction D1 and the second direction D2. The second electrical signal may be a direct-current signal. The second wiring line L2 may include the same conductive material as the conductive material included in the first wiring line L1 or may include a conductive material different from the conductive material included in the first wiring line L1. The second wiring line L2 that provides direct current may be referred to as a direct-current wiring line.

The semiconductor device may further include a second conductive contact CC2 that connects the second wiring line L2 and the second source/drain SD2 to each other. An end of the second conductive contact CC2 may be in contact with the second wiring line L2, and the other end of the second conductive contact CC2 may be in contact with the second source/drain SD2. The second conductive contact CC2 may be a conductive via contact that is filled in a via formed in an insulating layer between the second source/drain SD2 and the second wiring line L2.

The semiconductor device has a higher degree of integration, and thus, the distance between the gate electrode GE and the first conductive contact CC1 and the distance between the gate electrode GE and the second conductive contact CC2 have smaller values. For example, the distance between the gate electrode GE and the first conductive contact CC1 and the distance between the gate electrode GE and the second conductive contact CC2 may be in a range of greater than about 0 nm to about 10 nm (e.g., may be less than about 10 nm).

When an alternating-current signal is applied to the channel CH through the first wiring line L1, parasitic capacitance may be generated between the gate electrode GE and the first conductive contact CC1. The parasitic capacitance may degrade the performance of the semiconductor device. The parasitic capacitance may increase as an overlapping region between the gate electrode GE and the first conductive contact CC1 in the first direction D1 increases.

In an example embodiment, parasitic capacitance occurring in the semiconductor device may be reduced by reducing the overlapping area between the gate electrode GE and the first conductive contact CC1. For example, a height difference in the third direction D3 from a first surface of the gate electrode GE facing the first wiring line L1 to a first surface of the first source/drain SD1 in contact with the first conductive contact CC1 (that is, a first height h1 between a lower surface of the gate electrode GE and a lower surface of the first source/drain SD1) may be less than a height difference in the third direction D3 from a second surface of the gate electrode GE opposing the first surface of the gate electrode GE to a second surface of the first source/drain SD1 opposing the first surface of the first source/drain SD1 (that is, a second height h2 between an upper surface of the gate electrode GE and an upper surface of the first source/drain SD1). The first height h1 may be less than or equal to about ½ or about ⅓ of the second height h2. The first height h1 may be about 20 nm or less. The second height h2 may be about 30 nm or more. Here, the upper surface of the gate electrode GE, the upper surface of the first source/drain SD1, and an upper surface of the second source/drain SD2 may be referred to as corresponding surfaces, and the lower surface of the gate electrode GE, the lower surface of the first source/drain SD1, and a lower surface of the second source/drain SD2 may also be referred to as corresponding surfaces.

According to the example embodiments, the overlapping region between the gate electrode GE and the first conductive contact CC1 through which alternating current passes is reduced while the gate electrode GE is maintained to have a certain thickness, and thus, the performance of the semiconductor device may be improved.

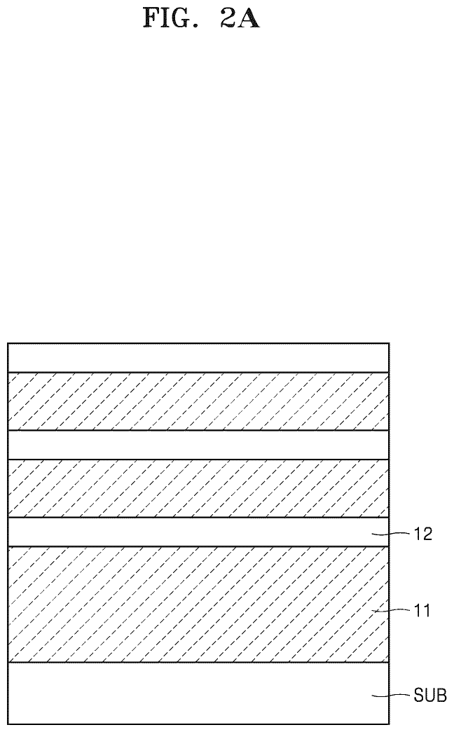

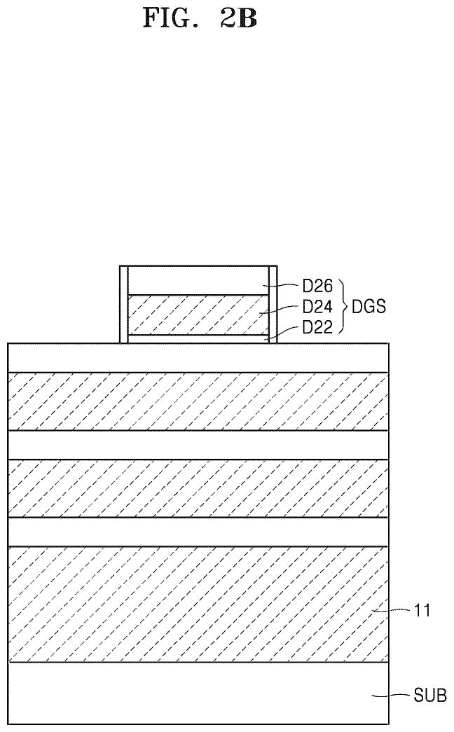

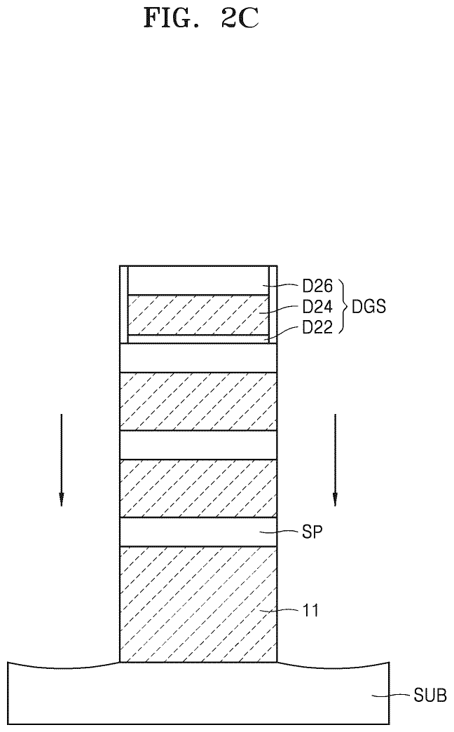

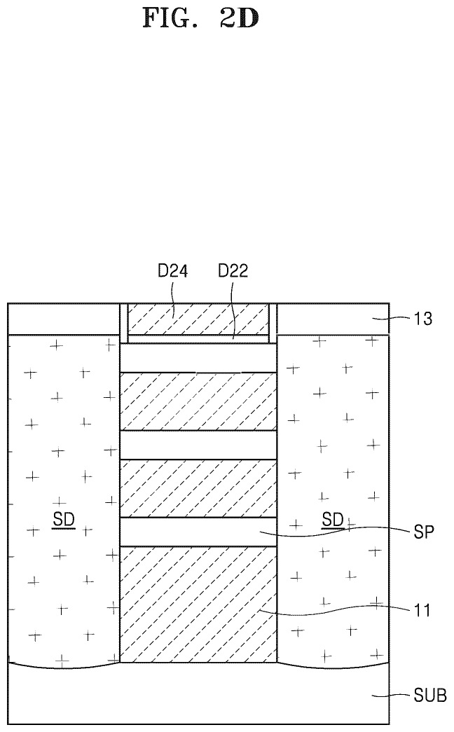

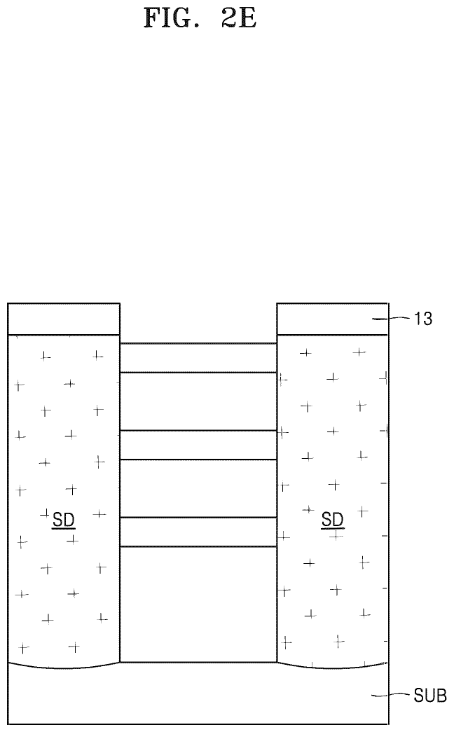

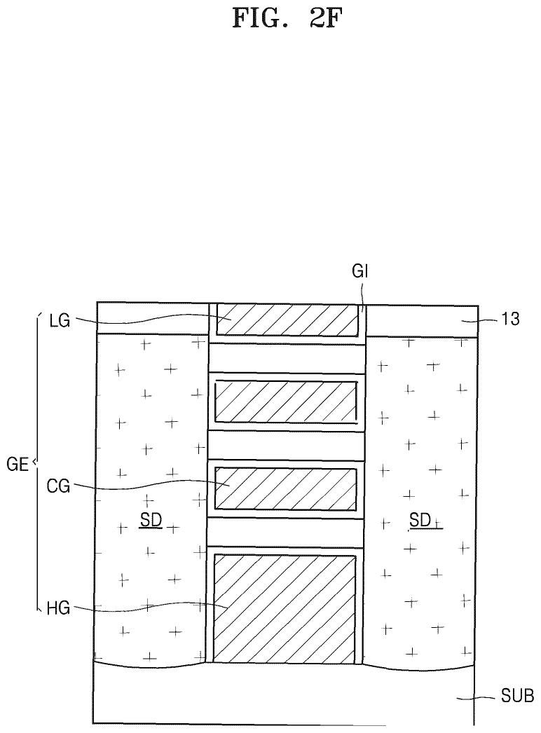

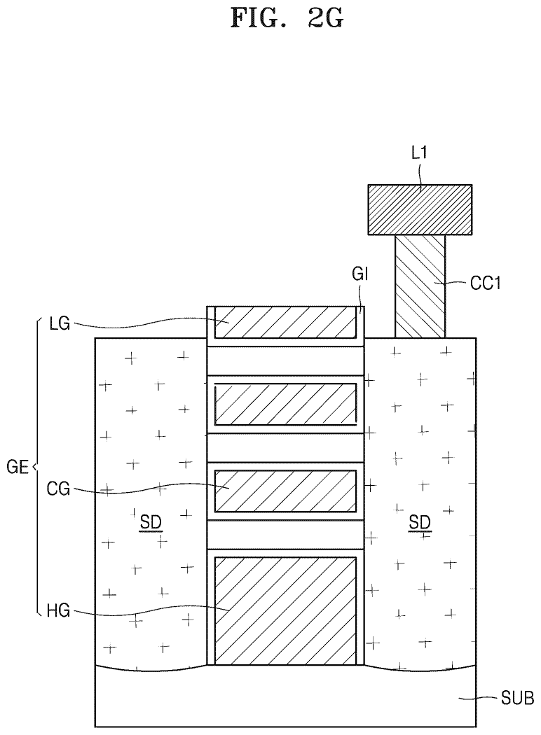

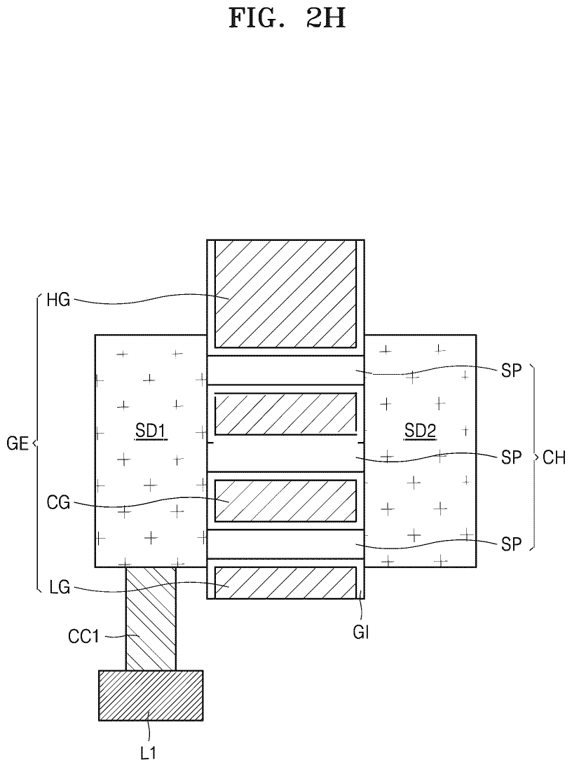

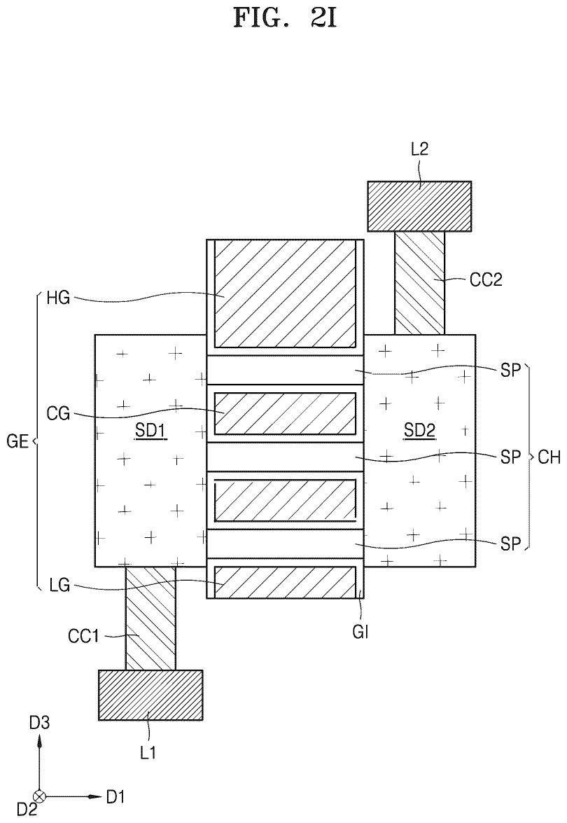

FIGS. 2A to 2I are reference diagrams describing a method of fabricating a semiconductor device according to an example embodiment.

Referring to FIG. 2A, a plurality of sacrificial layers 11 and a plurality of semiconductor layers 12 may be alternately stacked on a substrate SUB. The substrate SUB may include a semiconductor material. The sacrificial layers 11 and the semiconductor layers 12 may include semiconductor materials having different etching selectivities. In an example embodiment, the sacrificial layers 11 may include SiGe layers, and the semiconductor layers 12 may include Si layers. In an example embodiment, the Ge content in the sacrificial layers 11 may be constant. The SiGe layers forming the sacrificial layers 11 may have a constant Ge content within the range of about 5 atomic percent (at %) to about 60 at %, for example, within the range of about 10 at % to about 40 at %. The Ge content in the SiGe layers forming the sacrificial layers 11 may be variously selected as needed.

Referring to FIG. 2B, a dummy gate electrode structure DGS may be formed on an uppermost semiconductor layer 12 among the semiconductor layers 12. The dummy gate electrode structure DGS may have a structure in which an oxide layer D22, a dummy gate electrode layer D24, and a capping layer D26 are sequentially stacked. In an example embodiment, the oxide layer D22 may be a layer obtained by oxidizing a surface of the uppermost semiconductor layer 12. In another example embodiment, the oxide layer D22 may be formed by a deposition process. The dummy gate electrode layer D24 may include polysilicon, and the capping layer D26 may include a silicon nitride layer. A plurality of insulating spacers covering both side walls of the dummy gate electrode structure DGS may also be formed.

Referring to FIG. 2C, portions of the sacrificial layers 11 and the semiconductor layers 12 may be selectively etched using the dummy gate electrode structure DGS as an etching mask to form a plurality of semiconductor layers SP of a channel CH from the semiconductor layers 12. Further, a plurality of recesses may be formed in upper portions of the substrate SUB. The selective etching may be performed by a dry etching method, a wet etching method, or a combination thereof.

Referring to FIG. 2D, a plurality of source/drains SD filling the recesses may be formed. The source/drains SD may be formed by epitaxially growing a semiconductor material from a surface of the substrate SUB exposed at lower surfaces of the recesses and from side walls of the semiconductor layers SP. A first source/drain SD1 (refer to FIG. 2H) and a second source/drain SD2 (refer to FIG. 2H) may be later formed by etching the source/drains SD. However, example embodiments are not limited thereto. Depending on the fabricating method, the source/drains SD may become the first source/drain SD1 and the second source/drain SD2 without etching.

Subsequently, an insulating layer 13 covering a resultant structure including the source/drains SD may be formed. After forming the insulating layer 13, the capping layer D26 may be removed to expose the dummy gate electrode layer D24.

Referring to FIG. 2E, the dummy gate electrode layer D24 and the oxide layer D22 under the dummy gate electrode layer D24 may be removed, and then, the sacrificial layers 11 may be selectively removed through spaces from which the dummy gate electrode layer D24 and the oxide layer D22 are removed. In an example embodiment, the etching selectivity difference between the semiconductor layers SP and the sacrificial layers 11 may be used to selectively remove the sacrificial layers 11. A liquid or gaseous etchant may be used to selectively remove the sacrificial layers 11. In an example embodiment, an etchant based on CH3COOH, such as a mixture of CH3COOH, HNO3, and HF or a mixture of CH3COOH, H2O2, and HF, may be used to selectively remove the sacrificial layers 11. However, example embodiments are not limited thereto.

Referring to FIG. 2F, after selectively removing the sacrificial layers 11, gate insulating layers GI and a gate electrode GE may be formed in etched regions (that is, spaces from which the dummy gate electrode layer D24, the oxide layer D22, and the sacrificial layers 11 are removed). The gate insulating layers GI may be formed through an atomic layer deposition (ALD) process to cover the semiconductor layers SP. Subsequently, the gate electrode GE may be formed on the gate insulating layers GI. A first height of a lower surface of the source/drain SD relative to the substrate SUB is less than or equal to a second height of a lower surface of the gate electrode GE relative to the substrate SUB.

Referring to FIG. 2G, a first conductive contact CC1 may be formed on one of the source/drains SD, and a first wiring line L1 may be formed on the first conductive contact CC1. Although not shown in FIG. 2G, an insulating layer having the same thickness as the first conductive contact CC1 may be formed on a corresponding one of the source/drains SD, and a through-hole may be formed in the insulating layer to expose a surface of the corresponding one of the source/drains SD. The through-hole may be filled with a conductive material to form the first conductive contact CC1. Then, the first wiring line L1 may be formed on the insulating layer such that the first wiring line L1 may be in contact with the first conductive contact CC1.

Referring to FIG. 2H, the semiconductor device manufactured through the processes shown in FIGS. 2A to 2G may be flipped upside down by rotating the semiconductor device 180 degrees with respect to a third direction D3 (refer to FIG. 1A). The first source/drain SD1 and the second source/drain SD2 may be formed by etching the substrate SUB and the source/drains SD until the height of an exposed portion of the gate electrode GE reaches the second height h2 (refer to FIG. 1A).

Referring to FIG. 2I, a second conductive contact CC2 may be formed on the second source/drain SD2, and then, a second wiring line L2 making contacting with the second conductive contact CC2 may be formed. Although not shown in FIG. 2I, an insulating layer having the same thickness as the second conductive contact CC2 may be formed on the second source/drain SD2. A through-hole may be formed in the insulating layer to expose a surface of the second source/drain SD2, and the through-hole may be filled with a conductive material to form the second conductive contact CC2. The second wiring line L2 may be formed on the insulating layer such that the second wiring line L2 may be in contact with the second conductive contact CC2.

In the description of FIG. 2H, it is stated that the semiconductor device manufactured through the processes shown in FIG. 2A to 2G is flipped upside down. However, example embodiments are not limited thereto. In other example embodiments, the first wiring line L1 and the first conductive contact CC1, the channel CH, the first source/drain SD1 and the second source/drain SD2, the gate insulating layers GI, the gate electrode GE, the second conductive contact CC2, and the second wiring line L2 may be sequentially formed on the substrate SUB.

In the descriptions of FIGS. 1A and 1B, it is stated that alternating current is provided to the semiconductor device through the first wiring line L1. However, example embodiments are not limited thereto. Alternating current may be provided to the channel CH through the second wiring line L2. When alternating current is provided through the second wiring line L2, the height difference between an upper surface of the gate electrode GE and an upper surface of the second source/drain SD2 may be less than the height difference between a lower surface of the gate electrode GE and a lower surface of the second source/drain SD2.

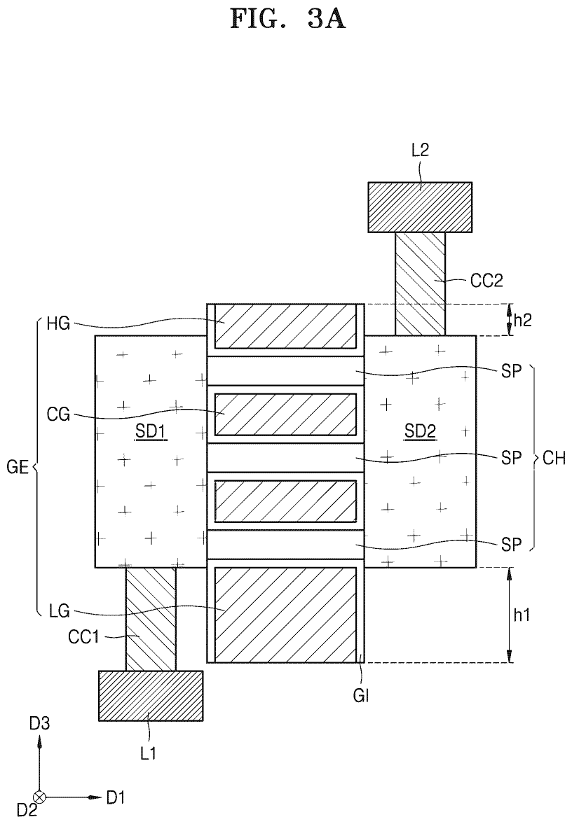

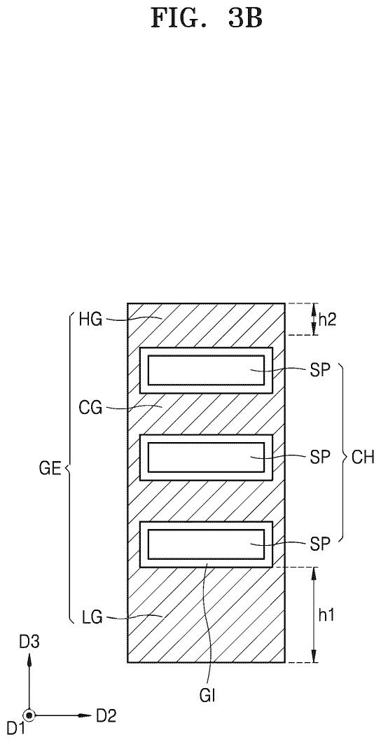

FIG. 3A is a view illustrating a semiconductor device according to another example embodiment, and FIG. 3B is a view illustrating the semiconductor device of FIG. 3A from a different perspective.

Referring to FIGS. 3A and 3B, the semiconductor device may receive alternating current through a second wiring line L2. Parasitic capacitance may be generated between a gate electrode GE and a second conductive contact CC2. To reduce the parasitic capacitance, a height difference in a third direction D3 from a first surface of the gate electrode GE facing the second wiring line L2 to a first surface of a second source/drain SD2 in contact with the second conductive contact CC2 (that is, a second height h2 between an upper surface of the gate electrode GE and an upper surface of the second source/drain SD2) may be less than a height difference in the third direction D3 from a second surface of the gate electrode GE opposing the first surface of the gate electrode GE to a second surface of the second source/drain SD2 opposing the first surface of the second source/drain SD2 (that is, a first height h1 between a lower surface of the gate electrode GE and a lower surface of the second source/drain SD2). The second height h2 may be less than or equal to about ½ or about ⅓ of the first height h1. The second height h2 may be about 20 nm or less. The first height h1 may be about 30 nm or more. The overall thickness of the gate electrode GE may be about 60 nm or more.

Parasitic capacitance may be reduced by reducing an overlapping region between the second conductive contact CC2 and the gate electrode GE that supply alternating current to a channel CH.

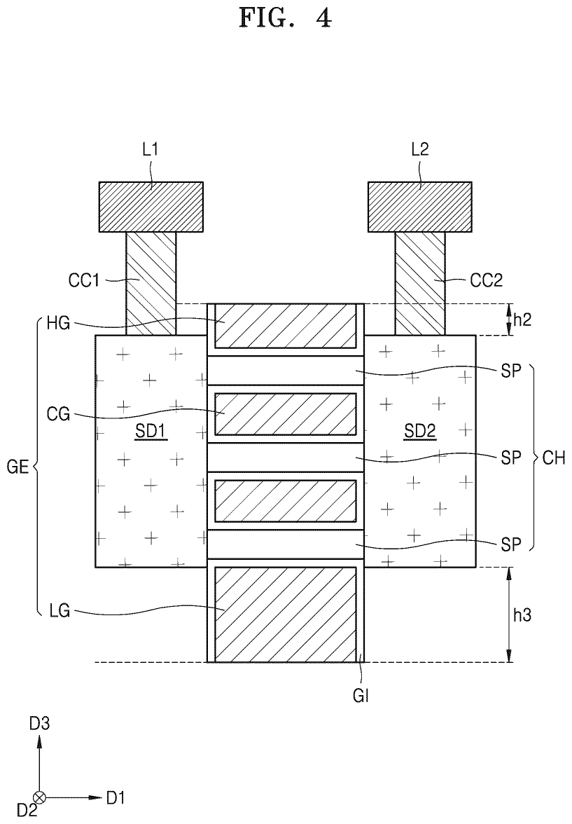

FIG. 4 is a view illustrating a semiconductor device according to another example embodiment. Comparing FIG. 4 with FIG. 3A, both a first wiring line L1 and a second wiring line L2 may be positioned above a gate electrode GE, a first conductive contact CC1 may electrically connect an upper surface of a first source/drain SD1 to the first wiring line L1, and a second conductive contact CC2 may electrically connect an upper surface of a second source/drain SD2 to the second wiring line L2.

A height difference h2 between an upper surface of the gate electrode GE and the upper surface of the first source/drain SD1 may be less than a height difference h3 between a lower surface of the gate electrode GE and a lower surface of the first source/drain SD1, and a height difference h2 between the upper surface of the gate electrode GE and the upper surface of the second source/drain SD2 may be less than a height difference h3 between the lower surface of the gate electrode GE and a lower surface of the second source/drain SD2.

The semiconductor device shown in FIG. 4 may reduce the generation of parasitic capacitance even when alternating current is supplied through one of the first wiring line L1 and the second wiring line L2, and direct current is supplied through the other.

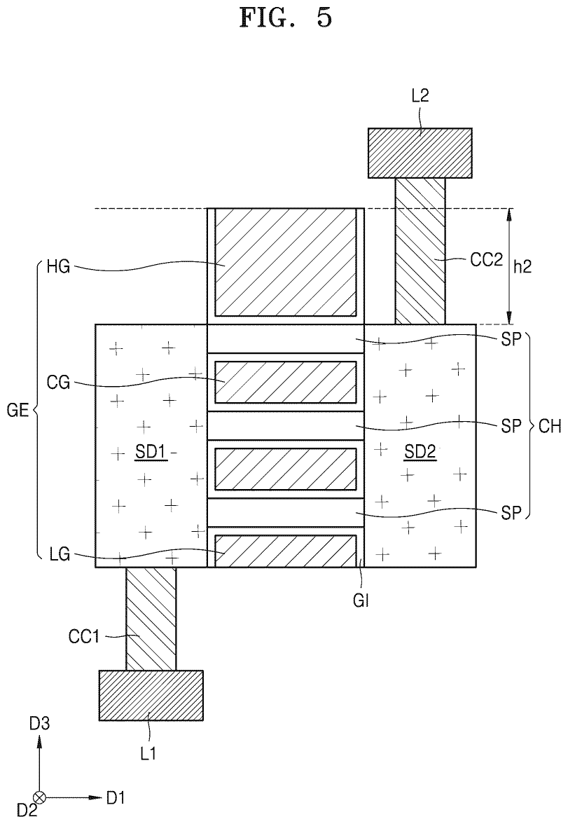

FIG. 5 is a view illustrating a semiconductor device according to another example embodiment. Comparing FIG. 5 with FIG. 1A, a lower surface of a gate electrode GE and a lower surface of a first source/drain SD1 may be on the same plane. That is, a height difference between the gate electrode GE and the first source/drain SD1 may be about zero. The semiconductor device shown in FIG. 5 may receive alternating current through a first wiring line L1 and a first conductive contact CC1. There is no overlapping region between the gate electrode GE and the first conductive contact CC1 in a first direction D1, and thus, parasitic capacitance may be substantially zero.

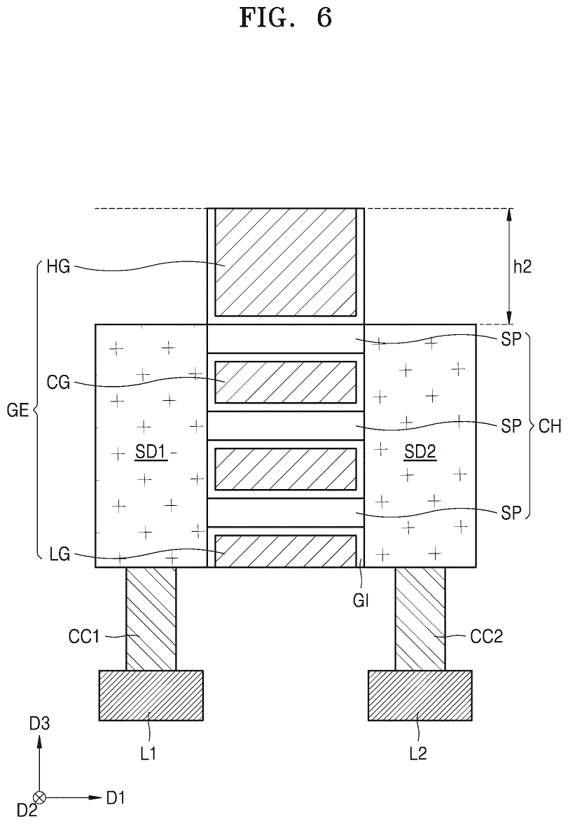

FIG. 6 is a view illustrating a semiconductor device according to another example embodiment. Comparing FIG. 6 with FIG. 5, a lower surface of a first source/drain SD1, a lower surface of a gate electrode GE, and a lower surface of a second source/drain SD2 may be on the same plane. That is, a height difference between the lower surface of the gate electrode GE and the lower surface of the first source/drain SD1 and a height difference between the lower surface of the gate electrode GE and the lower surface of the second source/drain SD2 may be substantially zero. The semiconductor device shown in FIG. 6 may receive alternating current through at least one selected from a first wiring line L1 and a second wiring line L2. There is no overlapping region between a first conductive contact CC1 and the gate electrode GE and between a second conductive contact CC2 and the gate electrode GE, and thus, parasitic capacitance may be substantially zero. In the semiconductor device shown in FIG. 6, the type of wiring line for supplying alternating current is not limited.

Although FIGS. 5 and 6 illustrate that the lower surface of the gate electrode GE is on the same plane as the lower surface of the first source/drain SD1 or the lower surface of the second source/drain SD2, example embodiments are not limited thereto. In other example embodiments, the lower surface of the gate electrode GE may be higher than the lower surface of the first source/drain SD1 or the lower surface of the second source/drain SD2.

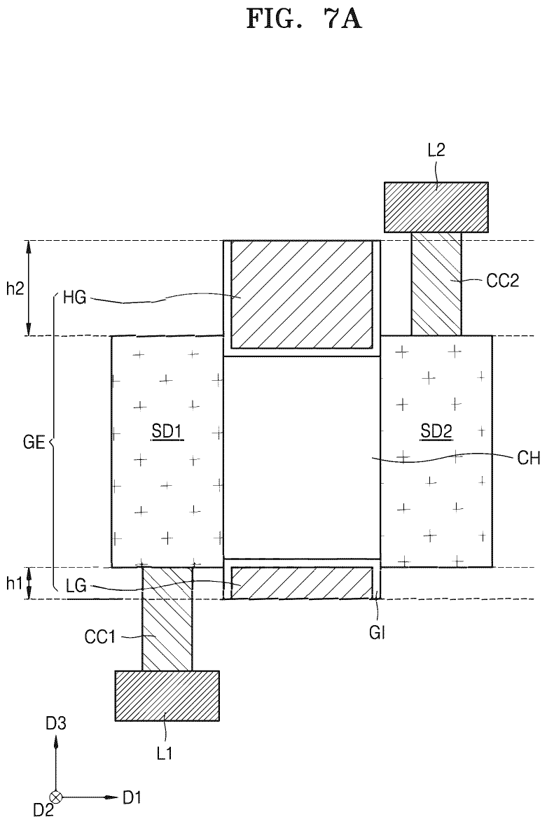

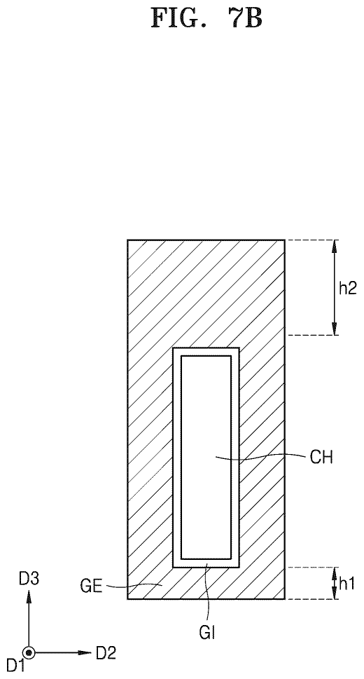

FIG. 7A is a view illustrating a semiconductor device according to another example embodiment, and FIG. 7B is a view illustrating the semiconductor device of FIG. 7A from a different perspective.

Referring to FIGS. 7A and 7B, a channel layer CH of the semiconductor device may include a single semiconductor layer. The size of the semiconductor layer shown in FIGS. 7A and 7B may be greater in a third direction D3 than in a second direction D2. A gate electrode GE may surround the channel CH. The gate electrode GE may surround the channel CH in a GAA structure. For example, four sides of the semiconductor layer SP of the channel CH may be surrounded by the gate electrode GE. Here, the four sides may include both sides in the second direction D2 and both sides in the third direction D3. The semiconductor device shown in FIGS. 7A and 7B may be referred to as a fin-type semiconductor device. The fin-type semiconductor device may have a relatively high degree of integration.

The semiconductor device may include a first source/drain SD1 and a second source/drain SD2 that are provided on both ends of the channel CH, respectively. A first wiring line L1 may apply a first electrical signal to the first source/drain SD1 through a first conductive contact CC1, and a second wiring line L2 may apply a second electrical signal to the second source/drain SD2 through a second conductive contact CC2.

A height difference in the third direction D3 from a first surface of the gate electrode GE facing the first wiring line L1 to a first surface of the first source/drain SD1 in contact with the first conductive contact CC1 (that is, a first height h1 between a lower surface of the gate electrode GE and a lower surface of the first source/drain SD1) may be less than a height difference in the third direction D3 from a second surface of the gate electrode GE opposing the first surface of the gate electrode GE to a second surface of the first source/drain SD1 opposing the first surface of the first source/drain SD1 (that is, a second height h2 between an upper surface of the gate electrode GE and an upper surface of the first source/drain SD1). The first height h1 may be less than or equal to about ½ or about ⅓ of the second height h2. The first height h1 may be about 20 nm or less. The second height h2 may be about 30 nm or more.

The semiconductor device of the example embodiment may receive alternating current through the first wiring line L1 and direct current through the second wiring line L2. According to the example embodiment, an overlapping region between the gate electrode GE and the first conductive contact CC1, through which alternating current flows, is reduced while the gate electrode GE is maintained to have a certain thickness, and thus, the performance of the semiconductor device may be improved.

The semiconductor devices described above may be applied to semiconductor apparatuses to which alternating current and direct current signals are supplied.

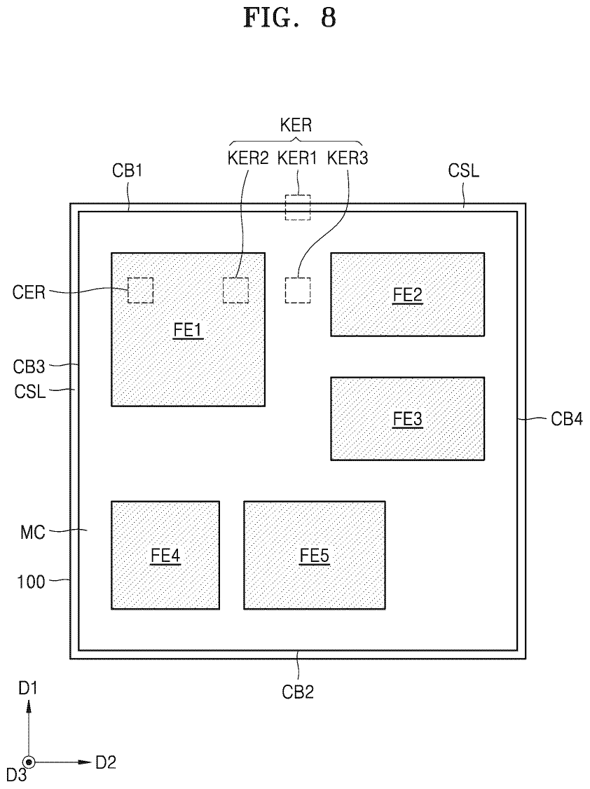

FIG. 8 is a plan view illustrating a semiconductor apparatus according to an example embodiment. Referring to FIG. 8, the semiconductor apparatus may include a main chip MC and cut scribe lanes CSL surrounding the main chip MC. The main chip MC may include first to fifth functional units FE1 to FE5 on a substrate 100. The substrate 100 may be a substrate obtained by dicing a semiconductor wafer. The substrate 100 may support the first to fifth functional units FE1 to FE5.

The main chip MC may include first to fourth boundaries CB1 to CB4. The first to fourth boundaries CB1 to CB4 may be defined between the main chip MC and the cut scribe lanes CSL. The cut scribe lanes CSL may surround the first to fourth boundaries CB1-CB4 of the main chip MC. In an example embodiment, the cut scribe lanes CSL may include a first key region KER1 adjacent to the first boundary CB1 of the main chip MC. In other words, the first key region KER1 may remain on the cut scribe lanes CSL even after a wafer dicing process.

Each of the first to fifth functional units FE1 to FE5 may be a functional block (also referred to as intellectual property (IP)) that forms an integrated circuit. Each of the first to fifth functional units FE1 to FE5 may include one selected from a memory block, an analog logic block, an input/output (I/O) logic block, a central processing unit (CPU) block, and a radio frequency (RF) block.

For example, the first functional unit FE1 may include a logic cell region CER and a second key region KER2. In other words, a key region KER may be provided not only on a scribe lane but also within a functional block. A third key region KER3 may be provided in a region between the first functional unit FE1 and the second functional unit FE2.

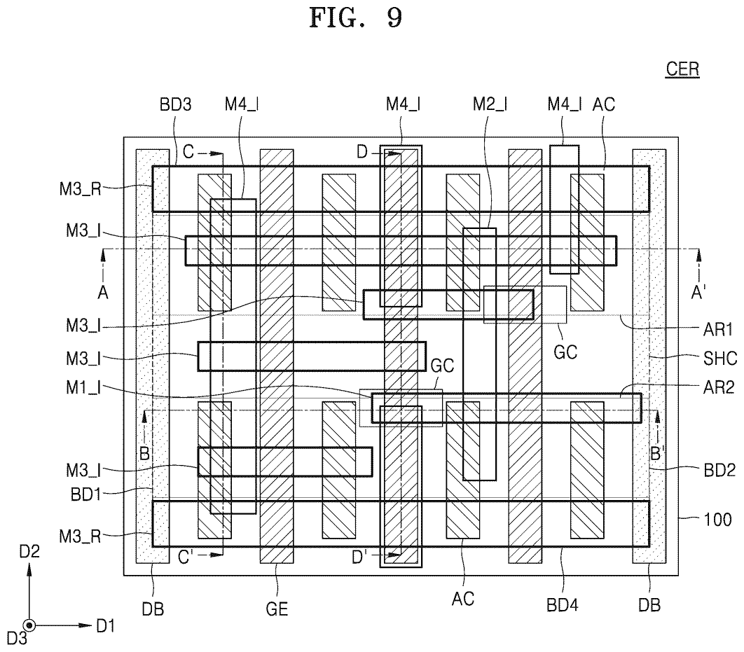

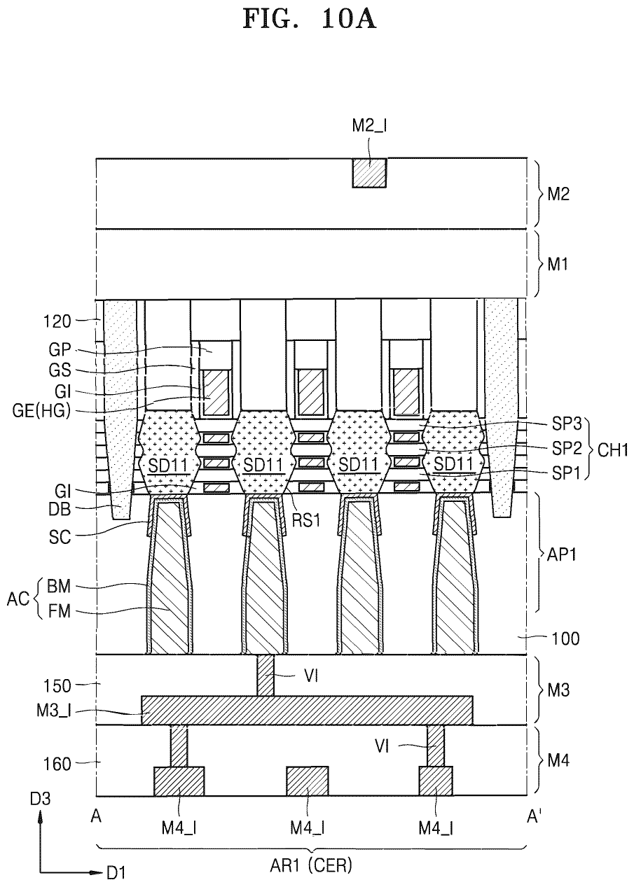

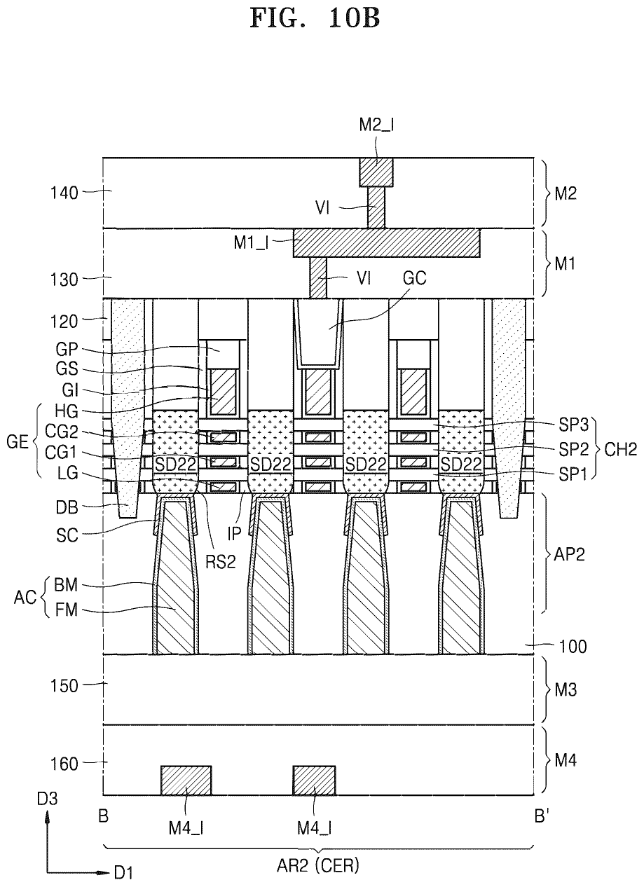

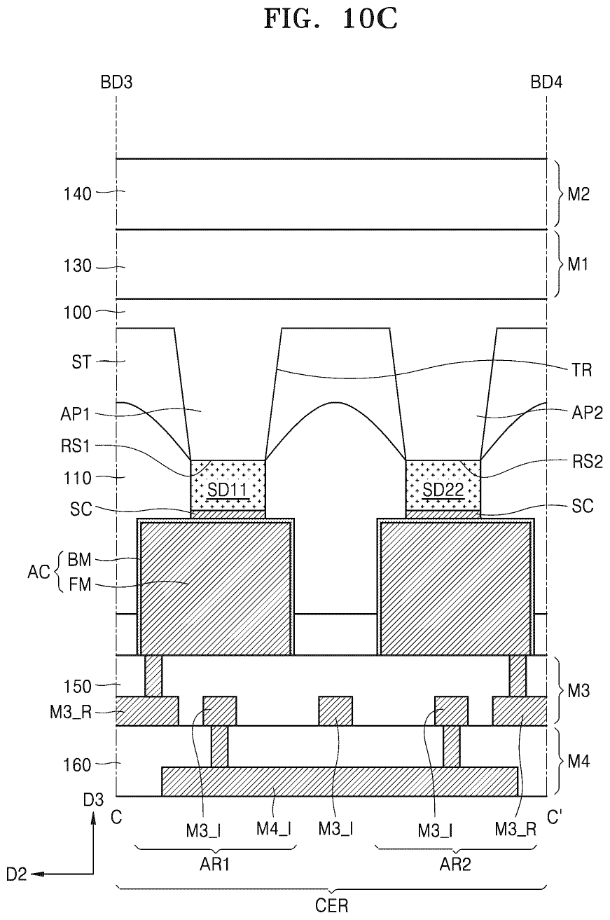

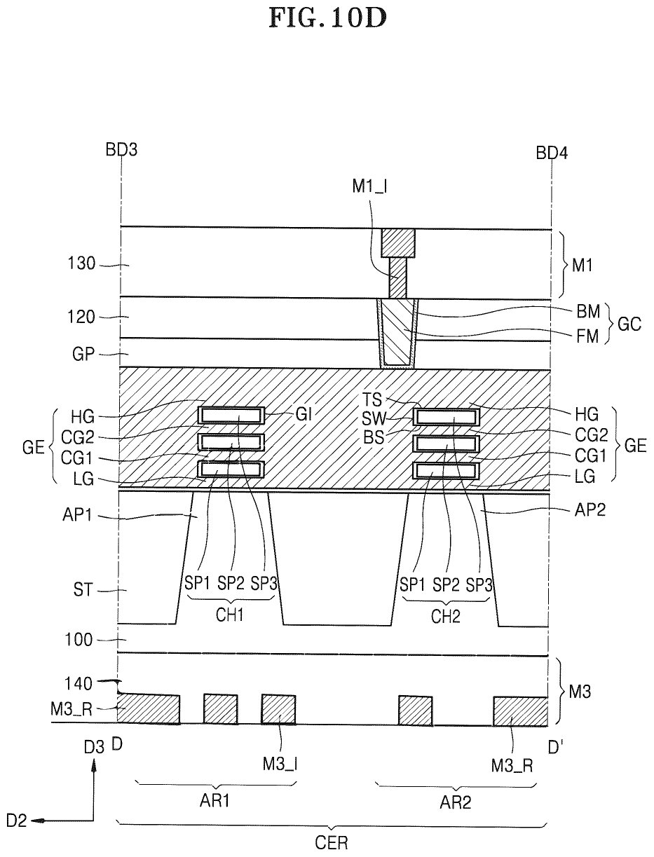

FIG. 9 is a plan view of the logic cell region CER shown in FIG. 8 and illustrate the semiconductor apparatus according to an example embodiment. FIGS. 10A to 10D are cross-sectional views taken along lines A-A′, B-B′, C-C′, and D-D′ of FIG. 9, respectively.

Referring to FIG. 9 and FIGS. 10A to 10D, the first functional unit FE1 of the semiconductor apparatus shown in FIG. 8 may include the logic cell region CER. The logic cell region CER may include a logic cell SHC that refers to a logic element configured to perform a specific function (such as AND, OR, XOR, XNOR, and/or inverter functions). The logic cell SHC of the logic cell region CER may include transistors forming a logic element and wiring lines connecting the transistors to each other. The substrate 100 may be a semiconductor substrate including silicon, germanium, silicon-germanium, or the like, or may be a compound semiconductor substrate. For example, the substrate 100 may be a silicon substrate.

The substrate 100 may include a first active region AR1 and a second active region AR2. Each of the first and second active regions AR1 and AR2 may extend in a first direction D1. In an embodiment, the first active region AR1 may be a p-type metal-oxide-semiconductor field-effect transistor (PMOSFET) region, and the second active region AR2 may be an n-type metal-oxide-semiconductor field-effect transistor (NMOSFET) region.

A first active pattern AP1 and a second active pattern AP2 may be defined by trenches TR formed in the substrate 100. The first active pattern AP1 may be provided in the first active region AR1, and the second active pattern AP2 may be provided in the second active region AR2. The first and second active patterns AP1 and AP2 may extend in a second direction D2. The first and second active patterns AP1 and AP2 may be vertically protruding portions of the substrate 100.

A device isolation layer ST may be provided in the substrate 100. The device isolation layer ST may fill the trenches TR. The device isolation layer ST may include a silicon oxide layer. The device isolation layer ST may not cover first and second channels CH1 and CH2 (described below).

The first channels CH1 may be provided on the first active pattern AP1. The second channels CH2 may be provided on the second active pattern AP2. Each of the first and second channels CH1 and CH2 may correspond to the channels CH described above. Each of the first and second channels CH1 and CH2 may include first to third semiconductor layers SP1, SP2, and SP3 that are sequentially stacked. The first to third semiconductor layers SP1, SP2 and SP3 may be apart from each other in a vertical direction (that is, a third direction D3).

Each of the first to third semiconductor layers SP1, SP2, and SP3 may be nanosheets. In other words, each of the first and second channels CH1 and CH2 may be a stack including stacked nanosheets. Each of the first to third semiconductor layers SP1, SP2, and SP3 may include silicon (Si), germanium (Ge), silicon-germanium (SiGe), or the like.

A plurality of 11th source/drains SD11 may be provided on the first active pattern AP1. A plurality of first recesses RS1 may be formed in upper portions of the first active pattern AP1. The 11th source/drains SD11 may be provided in the first recesses RS1, respectively. The 11th source/drains SD11 may be dopant regions doped with a first conductivity type (for example, a p-type). Each of the first channels CH1 may be disposed between a pair of 11th source/drains SD11. In other words, the first to third semiconductor layers SP1, SP2, and SP3 stacked in each of the first channel CH1 may connect a pair of 11th source/drains SD11 to each other. The pair of 11th source/drains SD11 may correspond to the first and second source/drains SD1 and SD2 described above.

A plurality of 22nd source/drains SD22 may be provided on the second active pattern AP2. A plurality of second recesses RS2 may be formed in upper portions of the second active pattern AP2. The 22nd source/drains SD22 may be provided in the second recesses RS2, respectively. The 22nd source/drains SD22 may be dopant regions doped with a second conductivity type (for example, an n-type). Each of the second channels CH2 may be disposed between a pair of 22nd source/drains SD22. In other words, the first to third semiconductor layers SP1, SP2, and SP3 stacked in each of the second channels CH2 may connect a pair of 22nd source/drains SD22 to each other. The pair of second source/drains SD22 may correspond to the first and second source/drains SD1 and SD2 described above.

The 11th and 22nd source/drains SD11 and SD22 may be epitaxial patterns formed by a selective epitaxial growth (SEG) process. For example, upper surfaces of the 11th and 22nd source/drains SD11 and SD22 may be higher than upper surfaces of the third semiconductor layers SP3. In another example, at least one of the upper surfaces of the 11th and 22nd source/drains SD11 and SD22 may be positioned at substantially the same level as the upper surfaces of the third semiconductor layers SP3.

In an example embodiment, the 11th source/drains SD11 may include a semiconductor element (for example, SiGe) having a lattice constant greater than the lattice constant of a semiconductor element included in the substrate 100. Thus, a pair of 11th source/drains SD11 may apply compressive stress to a first channel CH1 disposed between the pair of 11th source/drains SD11. The 22nd source/drains SD22 may include the same semiconductor element (e.g., Si) as the substrate 100.

Gate electrodes GE may extend in the second direction D2 across the first and second channels CH1 and CH2. The gate electrodes GE may overlap the first and second channels CH1 and CH2 in a direction perpendicular to the first and second channels CH1 and CH2.

Each of the gate electrodes GE may include a lower gate electrode LG between the active pattern AP1 or AP2 and a first semiconductor layer SP1, a first intermediate gate electrode CG1 between the first semiconductor layer SP1 and a second semiconductor layer SP2, a second intermediate gate electrode CG2 between the second semiconductor layer SP2 and a third semiconductor layer SP3, and an upper gate electrode HG above the third semiconductor layer SP3.

Referring to FIG. 10D, the gate electrodes GE may be provided on upper surfaces TS, lower surfaces BS, and side walls SW of the first to third semiconductor layers SP1, SP2, and SP3. The gate electrodes GE may surround the upper surfaces TS, the lower surfaces BS, and the side walls SW of the first to third semiconductor layers SP1, SP2, and SP3. In other words, the transistors of the current example embodiment may be three-dimensional field-effect transistors (for example, multi-bridge channel field-effect transistors (MBCFETs) or gate-all-around field-effect transistors (GAAFETs)) in which the gate electrodes GE surround the first and second channels CH1 and CH2 three-dimensionally.

A pair of gate spacers GS may be provided on both side walls of the upper gate electrode HG of each of the gate electrodes GE. The gate spacers GS may extend in the second direction D2 along the gate electrode GE. Upper surfaces of the gate spacers GS may be higher than an upper surface of the gate electrode GE. The upper surfaces of the gate spacers GS may be coplanar with an upper surface of a first interlayer insulating layer 110 (described below). In an example embodiment, the gate spacers GS may each include at least one selected from SiCN, SiCON, and SiN. In another example embodiment, the gate spacers GS may each have a multi-layer structure including at least two selected from SiCN, SiCON, and SiN.

A gate capping pattern GP may be provided on each of the gate electrodes GE. The gate capping pattern GP may extend in the second direction D2 along the gate electrode GE. The gate capping pattern GP may include a material having etching selectivity relative to first and second interlayer insulating layers 110 and 120 (described below). For example, the gate capping pattern GP may include at least one selected from SiON, SiCN, SiCON, and SiN.

Gate insulating layers GI may be arranged between the gate electrodes GE and the first channels CH1 and between the gate electrodes GE and the second channels CH2. The gate insulating layers GI may cover the upper surfaces TS, the lower surfaces BS, and the side walls SW of the first to third semiconductor layers SP1, SP2, and SP3. The gate insulating layers GI may cover an upper surface of the device isolation layer ST positioned under the gate electrode GE.

In an example embodiment, the gate insulating layers GI correspond to the gate insulating layers GI described above.

In another example embodiment, a semiconductor device of the disclosure may include negative capacitance field-effect transistors (NCFETs) that use negative capacitors. For example, the gate insulating layers GI may each include a ferroelectric material layer having ferroelectric properties and a paraelectric material layer having paraelectric properties.

The ferroelectric material layer may have negative capacitance, and the paraelectric material layer may have positive capacitance. For example, when two or more capacitors each having positive capacitance are connected in series to each other, the total capacitance of the capacitors is less than the capacitance of each of the capacitors. However, when the capacitance of at least one of two or more capacitors connected in series has a negative value, the total capacitance of the capacitors may be positive and may be greater than the absolute value of the capacitance of each of the capacitors.

When the ferroelectric material layer having negative capacitance and the paraelectric material layer having positive capacitance are connected in series, the total capacitance of the series-connected ferroelectric and paraelectric material layers may increase. Owing to such an increase in total capacitance, a transistor including the ferroelectric material layer may have a subthreshold swing (SS) of less than about 60 mV/decade at room temperature.

The ferroelectric material layer may have ferroelectric properties. The ferroelectric material layer may include, for example, at least one selected from hafnium oxide, hafnium zirconium oxide, barium strontium titanium oxide, barium titanium oxide, and lead zirconium titanium oxide. For example, the hafnium zirconium oxide may be a material obtained by doping hafnium oxide with zirconium (Zr). In another example, the hafnium zirconium oxide may be a compound of hafnium (Hf), zirconium (Zr), and oxygen (O).

The ferroelectric material layer may further include a dopant. For example, the dopant may include at least one selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material layer may vary depending on a ferroelectric material included in the ferroelectric material layer.

When the ferroelectric material layer includes hafnium oxide, the dopant included in the ferroelectric material layer may include, for example, at least one selected from gadolinium (Gd), silicon (Si), zirconium (Zr), aluminum (Al), and yttrium (Y).

When the dopant is aluminum (Al), the ferroelectric material layer may include aluminum (Al) in an amount of about 3 at % to about 8 at %. Here, the proportion of the dopant may be the ratio of aluminum to the sum of hafnium and aluminum.

When the dopant is silicon (Si), the ferroelectric material layer may include silicon (Si) in an amount of about 2 at % to about 10 at %. When the dopant is yttrium (Y), the ferroelectric material layer may include yttrium (Y) in an amount of about 2 at % to about 10 at %. When the dopant is gadolinium (Gd), the ferroelectric material layer may include gadolinium (Gd) in an amount of about 1 at % to about 7 at %. When the dopant is zirconium (Zr), the ferroelectric material layer may include zirconium (Zr) in an amount of about 50 at % to about 80 at %.

The paraelectric material layer may have paraelectric properties. The paraelectric material layer may include, for example, at least one selected from silicon oxide and metal oxide having a high dielectric constant. The metal oxide that may be included in the paraelectric material layer may include, for example, at least one selected from hafnium oxide, zirconium oxide, and aluminum oxide. However, example embodiments are not limited thereto.

The ferroelectric material layer and the paraelectric material layer may include the same material. The ferroelectric material layer may have ferroelectric properties, whereas the paraelectric material layer may not have ferroelectric properties. For example, when both the ferroelectric material layer and the paraelectric material layer include hafnium oxide, the crystal structure of hafnium oxide in the ferroelectric material layer differs from the crystal structure of hafnium oxide in the paraelectric material layer.

The ferroelectric material layer may have a thickness exhibiting ferroelectric properties. The thickness of the ferroelectric material layer may be, for example, from about 0.5 nm to about 10 nm, but example embodiments are not limited thereto. Each ferroelectric material has a critical thickness for exhibiting ferroelectric properties, and thus, the thickness of the ferroelectric material layer may vary depending on the ferroelectric material included in the ferroelectric material layer.

For example, each of the gate insulating layers GI may include a single ferroelectric material layer. In some example embodiments, each of the gate insulating layer GI may include a plurality of ferroelectric material layers arranged apart from each other. Each of the gate insulating layers GI may have a stacked structure in which a plurality of ferroelectric material layers and a plurality of paraelectric material layers are alternately layered.

Referring again to FIG. 10B, inner spacers IP may be provided on the second active pattern AP2. The inner spacers IP may be arranged between the lower gate electrodes LG, the first intermediate gate electrodes CG1, and the second intermediate gate electrodes CG2 of the gate electrodes GE and the 22nd second source/drains SD22. The inner spacers IP may be in direct contact with the 22nd second source/drains SD22. The lower gate electrodes LG, the first intermediate gate electrodes CG1, and the second intermediate gate electrodes CG2 of the gate electrodes GE may be arranged apart from the second source/drains SD22 by the inner spacers IP.

Each of the gate electrodes GE may include a first metal pattern and a second metal pattern provided on the first metal pattern. The first metal patterns may be provided on the gate insulating layers GI and may be adjacent to the first to third semiconductor layers SP1, SP2, and SP3. The first metal patterns may include a work function metal that adjusts the threshold voltage of the transistors. The threshold voltage of the transistors may be adjusted to an intended value by controlling the thickness and composition of the first metal patterns. For example, the lower gate electrodes LG, the first intermediate gate electrodes CG1, and the second intermediate gate electrodes CG2 of the gate electrodes GE may be formed by the first metal patterns including a work function metal.

Each of the first metal patterns may include a metal nitride layer. For example, each of the first metal patterns may include nitrogen (N) and at least one metal selected from titanium (Ti), tantalum (Ta), aluminum (Al), tungsten (W), and molybdenum (Mo). Furthermore, each of the first metal patterns may also include carbon (C). Each of the first metal patterns may include a plurality of stacked work function metal layers.

Each of the second metal patterns may include metal having lower resistance than the resistance of the first metal patterns. For example, each of the second metal patterns may include at least one metal selected from tungsten (W), aluminum (Al), titanium (Ti), and tantalum (Ta). The upper gate electrodes HG of the gate electrodes GE may include the first metal patterns and the second metal patterns provided on the first metal patterns.

The first interlayer insulating layer 110 may be provided on the substrate 100. The first interlayer insulating layer 110 may cover the gate spacers GS and the 11th and 22nd source/drains SD11 and SD22. An upper surface of the first interlayer insulating layer 110 may be coplanar with upper surfaces of the gate capping patterns GP and upper surfaces of the gate spacers GS. The second interlayer insulating layer 120 may be disposed on the first interlayer insulating layer 110 to cover the gate capping patterns GP. A third interlayer insulating layer 130 may be provided on the second interlayer insulating layer 120. A fourth interlayer insulating layer 140 may be provided on the third interlayer insulating layer 130. In addition, a fifth interlayer insulating layer 150 may be disposed on a lower surface of the substrate 100, and a sixth interlayer insulating layer 160 may be disposed on a lower surface of the fifth interlayer insulating layer 150. For example, each of the first to sixth interlayer insulating layers 110-160 may include a silicon oxide layer.

The logic cell SHC may have a first boundary BD1 and a second boundary BD2 that are opposite each other in the first direction D1. The first and second boundaries BD1 and BD2 may extend in the second direction D2. The logic cell SHC may have a third boundary BD3 and a fourth boundary BD4 that are opposite each other in the first direction D1. The third and fourth boundaries BD3 and BD4 may extend in the second direction D2.

A pair of isolation structures DB that are opposite to each other in the first direction D1 may be provided on both sides of the logic cell SHC, respectively. For example, the pair of isolation structures DB may be provided on the first and second boundaries BD1 and BD2 of the logic cell SHC. The isolation structures DB may extend parallel to the gate electrodes GE in the second direction D2. The isolation structures DB and gate electrodes GE adjacent to the isolation structures DB may be arranged with substantially the same pitch.

The isolation structures DB may penetrate the gate capping patterns GP and the gate electrodes GE and extend into the first and second active patterns AP1 and AP2. The isolation structures DB may penetrate upper portions of the first and second active patterns AP1 and AP2. The isolation structures DB may electrically isolate active regions of the logic cell SHC from active regions of an adjacent cell. In other words, the isolation structures DB may each be single diffusion break (SDB).

Active contacts AC may penetrate the substrate 100 and may be electrically connected to the 11th and 22nd source/drains SD11 and SD22, respectively. A pair of active contacts AC may be provided on both sides of each of the gate electrodes GE. In a planar view, the active contacts AC may have a bar shape extending in the third direction D3. The active contacts AC may each be a component of the first and second conductive contacts CC1 and CC2 described above. For example, each of the first and second conductive contacts CC1 and CC2 described above may be formed by a combination of an active contact and a conductive via.

Metal-semiconductor compound layers SC such as silicide layers may be arranged between the active contacts AC and the 11th and 22nd source/drains SD11 and SD22. The active contacts AC may be electrically connected to the 11th and 22nd source/drains SD11 and SD22 through the metal-semiconductor compound layers SC. For example, the metal-semiconductor compound layers SC may each include at least one selected from titanium silicide, tantalum silicide, tungsten silicide, nickel silicide, and cobalt silicide.

Gate contacts GC may penetrate the second interlayer insulating layer 120 and the gate capping patterns GP and may be electrically connected to the gate electrodes GE, respectively. In a planar view, the gate contacts GC may overlap the first and second active regions AR1 and AR2, respectively. For example, the gate contacts GC may be provided on the second active pattern AP2.

Each of the active contacts AC and the gate contacts GC may include a conductive pattern FM and a barrier pattern BM surrounding the conductive pattern FM. For example, the conductive pattern FM may include at least one metal selected from aluminum, copper, tungsten, molybdenum, and cobalt. The barrier pattern BM may cover side walls and a lower surface of the conductive pattern FM. The barrier pattern BM may include a metal layer/metal nitride layer. The metal layer may include at least one selected from titanium, tantalum, tungsten, nickel, cobalt, and platinum. The metal nitride layer may include at least one selected from titanium nitride (TiN), tantalum nitride (TaN), tungsten nitride (WN), nickel nitride (NiN), cobalt nitride (CoN), and platinum nitride (PtN).

A first wiring layer M1 may be provided in the third interlayer insulating layer 130, and a second wiring layer M2 may be provided in the fourth interlayer insulating layer 140. The first wiring layer M1 and the second wiring layer M2 may provide an electrical signal to the gate electrodes GE. At least a portion of the first wiring layer M1 and the second wiring layer M2 may be a gate wiring line. The electrical signal provided by the first wiring layer M1 and the second wiring layer M2 may be an alternating-current signal or a direct-current signal.

A third wiring layer M3 may be provided in the fifth interlayer insulating layer 150, and a fourth wiring layer M4 may be provided in the sixth interlayer insulating layer 160. The third wiring layer M3 and the fourth wiring layer M4 may provide an electrical signal to the 11th source/drains SD11 or the 22nd source/drains SD22. The electrical signal provided by the third wiring layer M3 and the fourth wiring layer M4 may be an alternating-current signal or a direct-current signal. For example, portions of the third wiring layer M3 and the fourth wiring layer M4 may be power wiring lines M3_R, and the other portions of the third wiring layer M3 and the fourth wiring layer M4 may be wiring lines (signal wiring lines) M3_I and M4_I through which signals are transmitted. The power wiring lines M3_R may provide direct current to power logic, and the signal wiring lines M3_I and M4_I may provide alternating current to logic.

Each of the first to fourth wiring layers M1, M2, M3, and M4 may further include vias VI. Wiring lines of the first wiring layer M1 and the gate contacts GC may be electrically connected to each other through the vias VI, or wiring lines of the third wiring layer M3 and the active contacts AC may be electrically connected to each other through the vias VI. In addition, the wiring lines of the first wiring layer M1 and wiring lines of the second wiring layer M2 may be electrically connected to each other through the vias VI included in the second wiring layer M2, and the wiring lines of the third wiring layer M3 and wiring lines of the fourth wiring layer M4 may be electrically connected to each other through the vias VI included in the fourth wiring layer M4.

The wiring lines of each of the wiring layers M1, M2, M3, and M4 may extend in the same direction and may be arranged apart from each other. For example, wiring lines M1_I included in the first wiring layer M1 and the wiring lines M3_I included in the third wiring layer M3 may extend in the first direction D1 and may be apart from each other in the second direction D2, while wiring lines M2_I included in the second wiring layer M2 and the wiring lines M4_I included in the fourth wiring layer M4 may extend in the second direction D2 and may be apart from each other in the first direction D1.

As described above, the active contacts AC and the gate contacts GC may be disposed in different layers. For example, the active contacts AC may penetrate the substrate 100, while the gate contact GC may penetrate the second interlayer insulating layer 120, thereby reducing or preventing a short circuit from occurring due to contact between the gate contacts GC and the active contacts AC. Furthermore, the active contacts AC and the gate electrodes GE do not overlap each other in the first direction D1 or the second direction D2, and thus, the generation of parasitic capacitance may be reduced or prevented.

The performance of the semiconductor devices of the disclosed example embodiments may be improved by reducing parasitic capacitance.

It should be understood that some example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel;
a first source/drain and a second source/drain being apart from each other in a first direction with the channel therebetween;
a gate electrode surrounding the channel;
an alternating-current wiring line being apart from the first source/drain in a second direction perpendicular to the first direction and configured to provide an alternating current to the channel; and
a first conductive contact connecting the alternating-current wiring line and the first source/drain to each other,
wherein a first height defined as a height difference in the second direction from a first surface of the gate electrode facing the alternating-current wiring line to a first surface of the first source/drain in contact with the first conductive contact is less than a second height defined as a height difference in the second direction from a second surface of the gate electrode opposing the first surface of the gate electrode to a second surface of the first source/drain opposing the first surface of the first source/drain.

2. The semiconductor device of claim 1, wherein the first height is less than or equal to ½ of the second height.

3. The semiconductor device of claim 1, wherein the first height is 20 nm or less.

4. The semiconductor device of claim 1, wherein the second height is 30 nm or more.

5. The semiconductor device of claim 1, wherein the gate electrode has a thickness of 60 nm or more in the second direction.

6. The semiconductor device of claim 1, wherein the first surface of the first source/drain and the first surface of the gate electrode are arranged on an identical plane.

7. The semiconductor device of claim 1, wherein a distance between the gate electrode and the first conductive contact is less than about 10 nm.

8. The semiconductor device of claim 1, further comprising:
a direct-current wiring line configured to provide a direct current to the channel; and
a second conductive contact connecting the direct-current wiring line and the second source/drain to each other.

9. The semiconductor device of claim 8, wherein the second conductive contact is in contact with a surface of the second source/drain corresponding to the second surface of the first source/drain.

10. The semiconductor device of claim 8, wherein the second conductive contact is in contact with a surface of the second source/drain corresponding to the first surface of the first source/drain.

11. The semiconductor device of claim 1, further comprising:
a gate wiring line configured to provide a gate signal to the gate electrode; and
a gate contact connecting the gate wiring line and the gate electrode to each other,
wherein the gate contact is in contact with a surface of the gate electrode corresponding to the second surface of the first source/drain.

12. The semiconductor device of claim 1, further comprising:
a substrate supporting the gate electrode, the first source/drain, and the second source/drain,
wherein the alternating-current wiring line is on a lower surface of the substrate, and the first conductive contact penetrates the substrate.

13. The semiconductor device of claim 12, wherein a height of a lower surface of the first source/drain relative to the substrate is less than or equal to a height of a lower surface of the gate electrode relative to the substrate.

14. The semiconductor device of claim 1, wherein the channel has a multi-bridge channel (MBC) structure.

15. The semiconductor device of claim 1, wherein the gate electrode has a gate-all-around (GAA) structure.

16. A method of fabricating a semiconductor device, the method comprising:
alternately stacking a plurality of sacrificial layers and a plurality of semiconductor layers on a substrate;
forming a dummy gate electrode structure on an uppermost semiconductor layer among the plurality of semiconductor layers that are stacked;
selectively etching portions of the plurality of sacrificial layers and the plurality of semiconductor layers by using the dummy gate electrode structure to form a channel from the plurality of semiconductor layers;
forming a first source/drain and a second source/drain at both ends of the channel on the substrate, respectively;
selectively removing the plurality of sacrificial layers,
forming a gate insulating layer and a gate electrode in regions at which the plurality of sacrificial layers that are selectively etched;
forming a first conductive contact on the first source/drain and an alternating-current wiring line on the first conductive contact; and
forming a second conductive contact on the second source/drain and a direct-current wiring line on the second conductive contact,
wherein a first height defined as a height difference from a first surface of the gate electrode facing the alternating-current wiring line to a first surface of the first source/drain in contact with the first conductive contact is less than a second height defined as a height difference from a second surface of the gate electrode opposing the first surface of the gate electrode to a second surface of the first source/drain opposing the first surface of the first source/drain.

17. The method of claim 16, wherein
the first height is less than or equal to ½ of the second height.

18. The method of claim 16, wherein the first height is 20 nm or less.

19. The method of claim 16, wherein the forming the second conductive contact forms the second conductive contact to contact a surface of the second source/drain corresponding to the second surface of the first source/drain.

20. The method of claim 16, further comprising:
forming a gate contact on the gate electrode and a gate wiring line on the gate contact such that
the gate contact contacts a surface of the gate electrode corresponding to the second surface of the first source/drain.
